(19) United States
(12) Patent Application Publication
(10) Pub. No.: US 2024/0308016 A1
(43) Pub. Date: Sep. 19, 2024

(54) WAFER GRINDING APPARATUS AND WAFER GRINDING METHOD

(71) Applicant: DISCO CORPORATION, Tokyo (JP)

(72) Inventors: Atsushi INOUE, Tokyo (JP); Kosuke ABE, Tokyo (JP); Taesup YOO, Tokyo (JP); Yusuke SATO, Tokyo (JP); Masahiro TAKEKAWA, Tokyo (JP)

(21) Appl. No.: 18/606,111

(22) Filed: Mar. 15, 2024

(30) Foreign Application Priority Data
Mar. 16, 2023 (JP) 2023-041835

(51) Int. Cl. B24B 7/22

(52) U.S. Cl. CPC B24B 7/228

(57) ABSTRACT

A wafer grinding method includes a first grinding step of grinding a first wafer for testing held on a chuck table to a finishing thickness, a thickness measuring step of measuring, at a plurality of locations in a radial direction, a thickness of the first wafer ground in the first grinding step, a nozzle positioning step of positioning a jetting nozzle directly above a portion of the first wafer having a thickness that is one of the thicknesses of the first wafer measured at the plurality of locations in the thickness measuring step and that is either greater or smaller than a reference thickness set beforehand, and a second grinding step of grinding a second wafer that is next held on the chuck table, while jetting cold water or warm water from the jetting nozzle to the second wafer.

### BACKGROUND OF THE INVENTION

### Field of the Invention

The present invention relates to a wafer grinding apparatus that grinds, by grindstones, a wafer held on a holding surface of a chuck table and a wafer grinding method.

### Description of the Related Art

In a manufacturing process for a semiconductor device as exemplified by an integrated circuit (IC) and a large-scale integration (LSI) circuit which are used in various kinds of electronic equipment, in order to obtain small and light semiconductor devices, a wafer is ground on a reverse side thereof and thinned to a predetermined thickness. A grinding apparatus for grinding a wafer employs a method of grinding the entire surface of the reverse side of the wafer by using a chuck table having a conical-shaped holding surface that is slightly sloped downward toward an outer circumference with the center as the vertex, holding the wafer on the holding surface of the chuck table, and causing a radial portion of the wafer to come into contact with lower surfaces of grindstones disposed in an annular shape (see, for example, Japanese Patent Laid-open No. 2008-264913, Japanese Patent Laid-open No. 2013-119123, and Japanese Patent Laid-open No. 2014-226749).

In such a grinding method, the tilt of the chuck table is adjusted such that the holding surface of the chuck table and grinding surfaces of the grindstones become parallel, thus allowing the wafer to be ground to a uniform in-plane thickness.

### SUMMARY OF THE INVENTION

Yet, due to thermal deformation of the chuck table alone caused by the processing heat generated during grinding processing, mere adjustment of the tilt relation between a rotational axis of the chuck table and a rotational axis of the grindstone is sometimes insufficient for grinding the wafer to a uniform thickness. Moreover, even when the wafer is separated from the chuck table after being processed, the chuck table is unable to become completely free of the processing heat; the chuck table accumulates processing heat and is thermally deformed every time the wafer is ground. Especially, in recent years, the in-plane thickness difference of the wafer is demanded to be 0.1 μm or thinner, and the grinding method of adjusting the thickness of the entire surface of wafer by adjusting the tilt relation between the chuck table and the grindstone, which has hitherto been used, is unable to meet this demand.

It is accordingly an object of the present invention to provide a wafer grinding apparatus and a wafer grinding method that are capable of grinding the wafer to a uninform thickness over its entire surface while reducing the in-plane thickness difference.

In accordance with an aspect of the present invention, there is provided a wafer grinding apparatus for grinding a wafer by a lower surface of an annular grindstone that is caused to come into contact with a radial portion of the wafer, the wafer grinding apparatus including a chuck table for holding the wafer by a conical-shaped holding surface having a center as a vertex, a table rotation mechanism for rotating the chuck table about a table rotational axis passing through the vertex, as an axis, a grinding unit for rotating the grindstone about a grindstone rotational axis passing through a center of the grindstone, as an axis, and grinding the wafer, a lifting/lowering mechanism for lifting and lowering the grinding unit in a direction approaching and separating from the holding surface, a thickness measuring instrument for measuring a thickness of the wafer ground by the grinding unit, a grinding water supply mechanism for supplying grinding water to an inner side of the grindstone, and a jetting nozzle for jetting cold water or warm water to at least a portion on an upper surface of the wafer at an outer side of the grindstone that is performing grinding processing, in which the wafer is ground in such a state where at least a portion of the wafer is caused to contract or swell in a ring shape by a rotation operation of the chuck table by the table rotation mechanism and the cold water or the warm water jetted from the jetting nozzle, in order to allow the wafer that has returned to room temperature after being ground to have a uniform thickness.

In accordance with another aspect of the present invention, there is provided a wafer grinding method performed with use of the wafer grinding apparatus described above, the wafer grinding method including a first grinding step of grinding a first wafer held on the chuck table to a finishing thickness, a thickness measuring step of measuring, at a plurality of locations in a radial direction, a thickness of the first wafer ground in the first grinding step, a nozzle positioning step of positioning the jetting nozzle directly above a portion of the first wafer having a thickness that is one of the thicknesses of the first wafer measured at the plurality of locations in the thickness measuring step and that is either greater or smaller than a reference thickness set beforehand, and a second grinding step of grinding a second wafer next held on the chuck table, by jetting warm water to the second wafer from the jetting nozzle positioned directly above a portion of the second wafer having a thickness greater than the reference thickness in the nozzle positioning step or jetting cold water to the second wafer from the jetting nozzle positioned directly above a portion of the second wafer having a thickness smaller than the reference thickness in the nozzle positioning step.

In accordance with a further aspect of the present invention, there is provided a wafer grinding method performed with use of the wafer grinding apparatus described above, the wafer grinding method including a first grinding step of grinding the wafer held on the chuck table to a thickness short of a finishing thickness, a thickness measuring step of measuring, at a plurality of locations in a radial direction, the thickness of the wafer ground in the first grinding step, a nozzle positioning step of positioning the jetting nozzle directly above a portion of the wafer having a thickness that is one of the thicknesses of the wafer measured at the plurality of locations in the thickness measuring step and that is either greater or smaller than a reference thickness set beforehand, and a second grinding step of grinding the wafer to the finishing thickness by jetting warm water to the wafer from the jetting nozzle positioned directly above the portion of the wafer having a thickness greater than the reference thickness in the nozzle positioning step or jetting cold water to the wafer from the jetting nozzle positioned directly above the portion of the wafer having a thickness smaller than the reference thickness in the nozzle positioning step.

According to the wafer grinding method of the present invention implemented with use of the grinding apparatus of the present invention, the thickness of the first wafer (for testing) that has been ground to a predetermined thickness in the first grinding step is measured at a plurality of locations in the radial direction in the next thickness measuring step, and then, in the next second grinding step, the second wafer (as a product) is ground while warm water is being jetted from the jetting nozzle to a portion of the second wafer corresponding to the portion of the first wafer having a thickness that is one of the thicknesses measured at the plurality of locations in the thickness measuring step and that is greater than a reference thickness set beforehand, i.e., while the portion of the second wafer having a thickness greater than the reference thickness after the grinding is being heated and caused to swell by warm water. Thus, the grinding amount in the second grinding step of the portion of the second wafer that has swelled by being heated (portion having a great thickness) becomes greater than those of other portions. Hence, when the second wafer returns to room temperature after the grinding processing, the thickness of the portion which had originally been greater than those of other portions becomes equivalent to those of other portions, so that the in-plane thickness is reduced, and the second wafer can be ground to a uniform thickness over the entire surface.

Alternatively, in the second grinding step, the second wafer is ground while cold water is being jetted from the jetting nozzle to the portion of the second wafer (as a product) corresponding to the portion of the first wafer having a thickness that is one of the thicknesses of the first wafer measured at a plurality of locations in the previous thickness measuring step and that is smaller than the reference thickness set beforehand, i.e., while the portion of the second wafer having a thickness smaller than the reference thickness after the grinding is being cooled and caused to contract by cold water. Thus, the grinding amount in the second grinding step of the portion of the second wafer that has contracted by being cooled (portion having a small thickness) becomes smaller than those of other portions. Hence, when the second wafer returns to room temperature after the grinding processing, the thickness of the portion which had originally been smaller than those of other portions becomes equivalent to those of other portions, so that the in-plane thickness is reduced, and the second wafer can be ground to a uniform thickness over the entire surface.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating, partially in a cutaway form, a wafer grinding apparatus according to the present invention;

FIG. 2 is a cross-sectional side view of a main portion of the grinding apparatus illustrating a first grinding step in a wafer grinding method according to a first embodiment of a first invention;

FIG. 3A is a cross-sectional side view of the main portion of the grinding apparatus illustrating a thickness measuring step in the wafer grinding method according to the first embodiment of the first invention;

FIG. 3B is a graph illustrating a thickness distribution of a first wafer in a radial direction;

FIG. 4 is a cross-sectional side view of the main portion of the grinding apparatus illustrating a nozzle positioning step and a second grinding step in the wafer grinding method according to the first embodiment of the first invention;

FIG. 5 is a cross-sectional side view of the main portion of the grinding apparatus illustrating a tilt adjusting step in the wafer grinding method according to the first embodiment of the first invention;

FIG. 6 is a cross-sectional side view of the main portion of the grinding apparatus illustrating the first grinding step in the wafer grinding method according to a second embodiment of the first invention;

FIG. 7A is a cross-sectional side view of the main portion of the grinding apparatus illustrating the thickness measuring step in the wafer grinding method according to the second embodiment of the first invention;

FIG. 7B is a graph illustrating the thickness distribution of the first wafer in the radial direction;

FIG. 8 is a cross-sectional side view of the main portion of the grinding apparatus illustrating the nozzle positioning step and the second grinding step in the wafer grinding method according to the second embodiment of the first invention;

FIG. 9 is a cross-sectional side view of the main portion of the grinding apparatus illustrating the tilt adjusting step in the wafer grinding method according to the second embodiment of the first invention;

FIG. 10A is a cross-sectional side view of the main portion of the grinding apparatus illustrating the thickness measuring step in the wafer grinding method according to another embodiment of the first invention;

FIG. 10B is a graph illustrating a thickness distribution of a third wafer in the radial direction;

FIG. 11 is a cross-sectional side view of the main portion of the grinding apparatus illustrating the first grinding step in the wafer grinding method according to a second invention;

FIG. 12A is a cross-sectional side view of the main portion of the grinding apparatus illustrating the thickness measuring step in the wafer grinding method according to the second invention;

FIG. 12B is a graph illustrating the thickness distribution of the third wafer in the radial direction; and

FIG. 13 is a cross-sectional side view of the main portion of the grinding apparatus illustrating the second grinding step in the wafer grinding method according to the second invention.

### DETAILED DESCRIPTION OF THE PREFERRED EMBODIMENTS

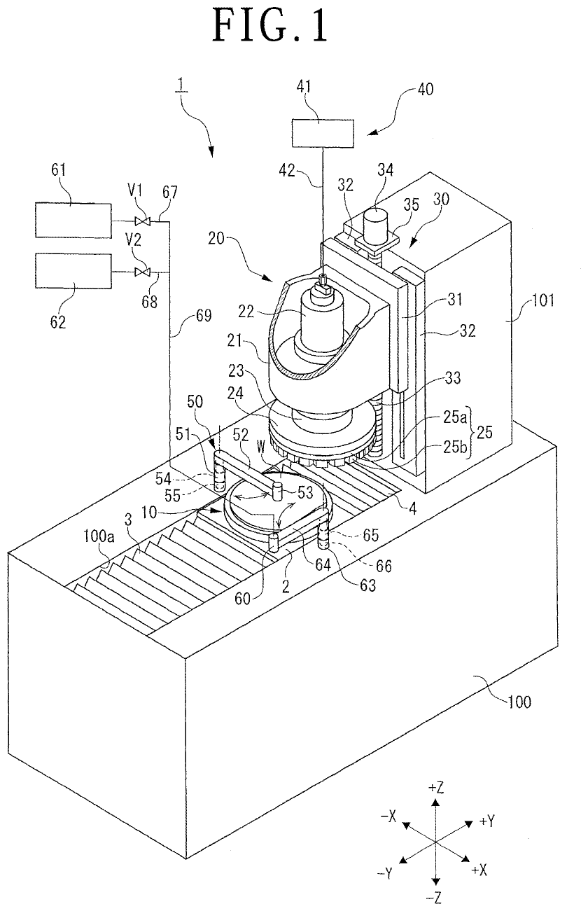

Embodiments of the present invention will hereinafter be described in reference to the attached drawings. First, a configuration of a wafer grinding apparatus according to the present invention will be described. Note that, in the following description, arrow directions illustrated in FIG. 1 represent an X-axis direction (left-right direction), a Y-axis direction (forward-backward direction), and a Z-axis direction (up-down direction).

A grinding apparatus 1 illustrated in FIG. 1 performs grinding processing on a circular plate-shaped wafer W as a workpiece and includes the following components.

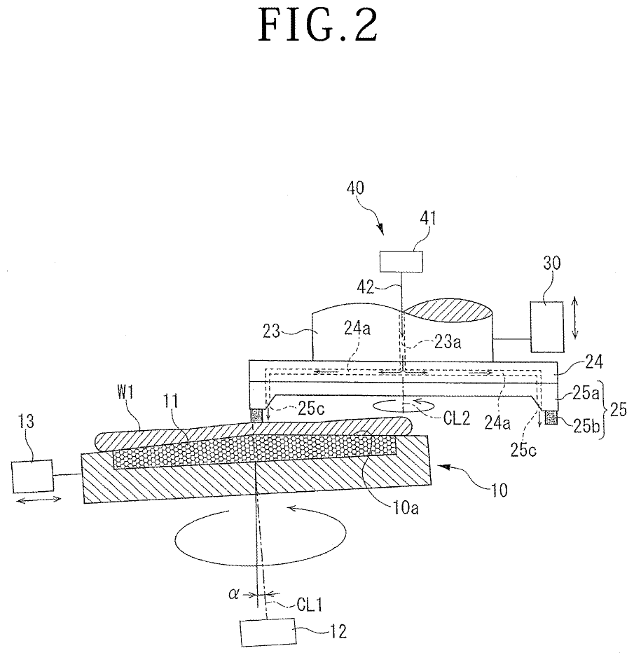

Specifically, the grinding apparatus 1 includes, as main components, a chuck table 10 that holds the wafer W and rotates, a table rotation mechanism 12 (see FIG. 2) that rotationally drives the chuck table 10, a grinding unit 20 that performs grinding processing on the wafer W held on the chuck table 10, a lifting/lowering mechanism 30 that lifts and lowers the grinding unit 20 in a vertical direction (Z-axis direction) relative to a holding surface 10a (see FIG. 2) of the chuck table 10, a grinding water supply mechanism 40 that supplies grinding water to an inner side of a plurality of grindstones 25b (see FIG. 2) disposed in an annular ring shape, during the grinding processing of the wafer W, a thickness measuring instrument 50 that measures a thickness of the wafer W that is being ground, and a jetting nozzle 60 that jets cold water or warm water to at least one portion (outer circumferential portion in the present embodiment) on an upper surface of the wafer W that is being ground.

Here, the wafer W is configured of a single crystal silicon base material and has a face side facing downward in the state illustrated in FIG. 1 and having a plurality of unillustrated devices formed thereon. These devices are protected by an unillustrated protection tape affixed to the face side of the wafer W. The wafer W is held on the face side thereof (lower surface in FIG. 1) under suction on the holding surface 10a of the chuck table 10 via the protection tape and is ground on the reverse side thereof (upper surface in FIG. 1) by the grindstones 25b of the grinding unit 20 while being supplied with grinding water from the grinding water supply mechanism 40.

Next, the configuration of each of the chuck table 10, the table rotation mechanism 12, the grinding unit 20, the lifting/lowering mechanism 30, the grinding water supply mechanism 40, the thickness measuring instrument 50, and the jetting nozzle 60, which are main components of the grinding apparatus 1, will be described.

The chuck table 10 is a circular plate-shaped member and has a circular plate-shaped porous member 11 incorporated in the center thereof, as illustrated in FIG. 2. Note that the porous member 11 is configured by porous ceramic and the like and is selectively connected to an unillustrated suction source such as a vacuum pump.

Here, an upper surface of the chuck table 10 configures the conical-shaped holding surface 10a that is sloped downward toward the outer circumference with the center as the vertex, as illustrated in FIG. 2. On this holding surface 10a, the face side (lower surface in FIG. 2) of the wafer W is held with the unillustrated protection tape laid below. Note that, in FIG. 2, the slope of the conical-shaped holding surface 10a of the chuck table 10 is illustrated in an exaggerated manner; in practice, this slope is so slight that it cannot be visibly recognized by the naked eye.

The chuck table 10 is rotationally driven in an arrow direction (counterclockwise direction) by the table rotation mechanism 12 illustrated in FIG. 2, about a table rotational axis CL1 passing through the vertex of the holding surface 10a. That is, the chuck table 10 has an unillustrated table rotational axis integrally and vertically extending downward from the center. The chuck table 10 is rotationally driven at a predetermined speed with this table rotational axis used as the table rotational axis CL1 by the table rotation mechanism 12. Here, the table rotation mechanism 12 includes an unillustrated servomotor as a drive source and an unillustrated encoder that detects the rotational speed, the rotation direction, the rotation angle, and the like of the servomotor, for example.

As illustrated in FIG. 1, the grinding apparatus 1 according to the present embodiment includes a rectangular box-shaped base 100 elongate in the Y-axis direction (forward-rearward direction), and the chuck table 10 faces a rectangular opening 100a that is open in the base 100 and that is elongate in the Y-axis direction. The portion of the opening 100a around the chuck table 10 is covered by a rectangular plate-shaped cover 2, and portions of the opening 100a in the front and rear (−Y-axis direction and +Y-axis direction) of the cover 2 are covered respectively by bellows-shaped extendable covers 3 and 4 that move along with the cover 2 and extend and contract. Hence, no matter where the chuck table 10 is located on the Y-axis, the opening 100a is always closed by the cover 2 and the extendable covers 3 and 4, preventing foreign matter from entering inside the base 100 from the opening 100a.

Further, the chuck table 10 can be adjusted in tilt by an unillustrated tilt adjusting mechanism. Specifically, the table rotational axis CL1 of the chuck table 10 is tilted by an illustrated angle α with respect to a vertical line, and the tilt of the holding surface 10a of the chuck table 10 with respect to a horizontal plane can be adjusted.

Further, the chuck table 10 can be moved in a horizontal direction (Y-axis direction) by a horizontal movement mechanism 13 (see FIG. 2) housed in the base 100. Note that the horizontal movement mechanism 13 is configured by a known ball screw mechanism, and thus the detailed explanation regarding this mechanism is omitted.

As illustrated in FIG. 1, the grinding unit 20 includes a spindle motor 22 that is a rotational drive source housed in a holder 21, a vertical spindle 23 that is rotationally driven by the spindle motor 22, a circular plate-shaped mount 24 attached to a lower end of the spindle 23, and a grinding wheel 25 mounted in an attachable/detachable manner to a lower surface of the mount 24. Here, the grinding wheel 25 is configured by a circular plate-shaped base 25a and the plurality of grindstones 25b as a processing tool attached in an annular ring shape to a lower surface of the base 25a. Each of the grindstones 25b is a rectangular block-shaped processing tool for grinding the wafer W, and the lower surface thereof configures a grinding surface that comes into contact with the upper surface (to-be-ground surface) of the wafer W.

Note that, while the spindle 23 of the grinding unit 20 rotates about a grindstone rotational axis CL2, together with the mount 24 and the grinding wheel 25, in the grinding apparatus 1 according to the present embodiment, the grindstone rotational axis CL2 is disposed vertically and cannot be tilted. In contrast, the table rotational axis CL1 of the chuck table 10 can be tilted by a predetermined angle α as illustrated in FIG. 2, for example, with respect to the vertical grindstone rotational axis CL2, by the unillustrated tilt adjusting mechanism, and the holding surface 10a of the chuck table 10 is thereby tilted by the angle α with respect to the horizontal plane.

The lifting/lowering mechanism 30 is a mechanism that causes the grinding unit 20 to approach and separate from the holding surface 10a of the chuck table 10. As illustrated in FIG. 1, the lifting/lowering mechanism 30 is disposed on an end surface (front surface) in the −Y axis direction of a rectangular box-shaped column 101 erected vertically on an end portion (rear end portion) in the +Y-axis direction of the upper surface of the base 100. The lifting/lowering mechanism 30 lifts and lowers a rectangular plate-shaped lifting/lowering plate 31 attached to a rear surface of the holder 21 of the grinding unit 20, in the Z-axis direction along a pair of left and right guide rails 32, together with the holder 21 and the spindle 23 and the grinding wheel 25 that are held by the holder 21. Here, the pair of left and right guide rails 32 are disposed vertically and in parallel with each other on the front surface of the column 101.

In addition, between the pair of left and right guide rails 32, a rotatable ball screw 33 is erected vertically along the Z-axis direction (up-down direction), and has an upper end coupled to a servomotor 34 that is a driving source and that is capable of forward/reverse rotation. Here, the servomotor 34 is attached in a vertical state to the column 101 via a rectangular plate-shaped bracket 35 attached to an upper surface of the column 101. Further, a lower end of the ball screw 33 is supported in a rotatable manner by the column 101, and to this ball screw 33, an unillustrated nut member projecting horizontally toward the rear side (+Y-axis direction) is screwed on a rear surface of the lifting/lowering plate 31.

Accordingly, when the servomotor 34 is activated and the ball screw 33 is subjected to forward/reverse rotation, the lifting/lowering plate 31 to which the unillustrated nut member screwed to the ball screw 33 is attached moves vertically together with the grinding unit 20 along the pair of guide rails 32, so that the grinding unit 20 is lifted and lowered, and the amount of grinding (grinding allowance) of the wafer W by the grindstones 25b is set.

The grinding water supply mechanism 40 supplies grinding water such as pure water toward a grinding region which is a portion where the grindstones 25 performing grinding processing and the wafer W come into contact with each other, and jets grinding water from an inner side of the annular grindstones 25b that rotate during the grinding processing. More specifically, as illustrated in FIG. 1, the grinding water supply mechanism 40 includes a grinding water supply source 41 such as a water pump, and a pipe 42 extending from this grinding water supply source 41 is connected to an unillustrated supply channel formed vertically along the axis of the spindle motor 22. The unillustrated supply channel formed in the spindle motor 22 is connected to a supply channel 23a formed vertically along the axis of the spindle 23 illustrated in FIG. 2, and the supply channel 23a is connected to a plurality of supply channels 24a extending radially outward in a radial direction from a center of the mount 24. Further, the base 25a of the grinding wheel 25 is formed with a plurality of nozzles 25c each extending vertically downward from the respective supply channels 24a formed in the mount 24.

Accordingly, the grinding water that is supplied from the grinding water supply source 41 to the spindle motor 22 through the pipe 42 flows through the supply channel 23a formed in the spindle 23 illustrated in FIG. 2 and the plurality of supply channels 24a formed in the mount 24 and is jetted toward the upper surface of the wafer W from the plurality of nozzles 25c formed in the base 25a of the grinding wheel 25. Note that, in the present embodiment, as described below, the wafer W includes a first wafer W1 for testing (dummy) and a second wafer W2 as a product.

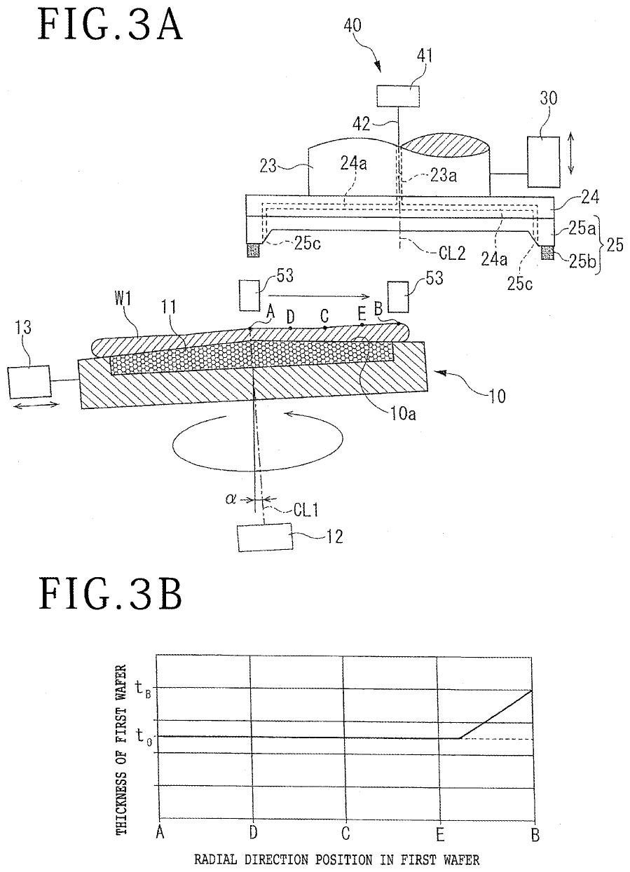

The thickness measuring instrument 50 optically measures the thickness of the wafer W (first wafer W1 for testing (dummy) in the present embodiment) in a non-contact manner. As illustrated in FIG. 1, the thickness measuring instrument 50 includes a thickness sensor 53 that is attached to a distal end of an arm 52 extending horizontally from an upper end of a support shaft 51 which is vertically erected in a rotatable manner near the chuck table 10 on the base 100. Here, the support shaft 51 incorporates a motor 54 that is a drive source for rotating the support shaft 51 and an encoder 55 that detects the rotation angle and the rotation direction of the motor 54. Note that the thickness sensor 53 measures the thickness of the first wafer W1 in a non-contact manner by emitting infrared light as measuring light toward the first wafer W1 and analyzing interfering light of reflecting light that has been reflected both at the upper surface (reverse side) and the lower surface (face side) of the first wafer W1 (see FIG. 3A). Alternatively, the thickness measuring instrument 50 may measure the thickness of the wafer W by transmitting ultrasonic vibrations toward the wafer W and receiving the ultrasonic vibrations that have been reflected at both the upper surface and the lower surface of the wafer W.

Accordingly, when the motor 54 is activated and the arm 52 is swung on the upper side of the first wafer W1 about the support shaft 51, the thickness sensor 53 attached to the distal end of the arm 52 can be moved in a radial direction of the first wafer W1, and the thickness of any portion of the first wafer W1 in the radial direction can be measured.

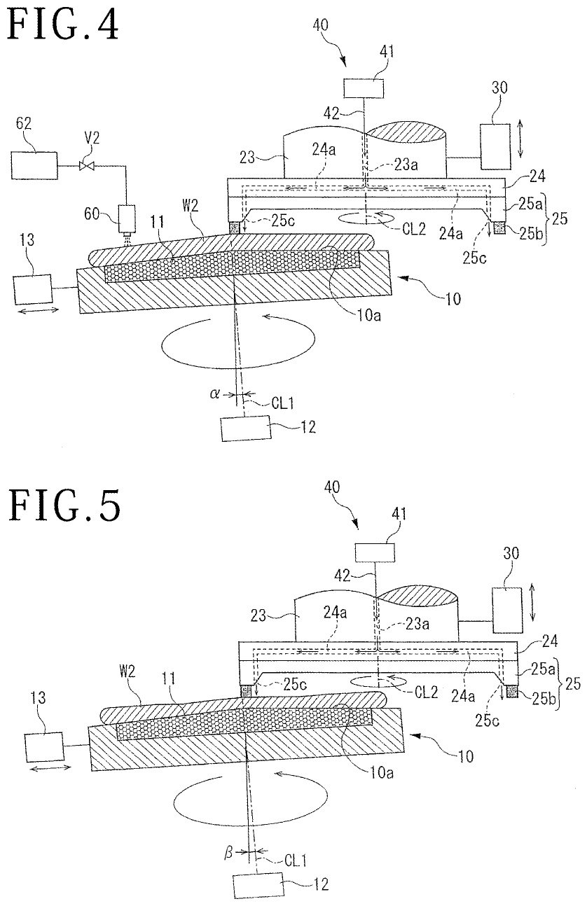

The jetting nozzle 60 jets cold water or warm water onto at least one portion (in the present embodiment, the outer circumferential portion (see FIG. 4)) on the upper surface of the wafer W (in the present embodiment, the second wafer W2) from a cold water supply source 61 or a warm water supply source 62 illustrated in FIG. 1. The jetting nozzle 60 is attached to a distal end of an arm 64 extending horizontally from an upper end of a support shaft 63 which is erected vertically in a rotatable manner near the chuck table 10 on the base 100. Here, the support shaft 63 incorporates a motor 65 which is a drive source that rotates the support shaft 63 and an encoder 66 that detects the rotation angle and the rotation direction of the motor 65.

As illustrated in FIG. 1, pipes 67 and 68 respectively extending from the cold water supply source 61 and the warm water supply source 62 merge to one pipe 69, which is connected to the jetting nozzle 60. Note that the pipes 67 and 68 are provided with on/off valves V1 and V2, respectively.

Accordingly, when the motor 65 is activated and the arm 64 is swung on the upper side of the second wafer W2 about the support shaft 63, the jetting nozzle 60 attached to the distal end of the arm 64 is moved in the radial direction of the second wafer W2, and cold water or warm water can be jetted onto any portion on the upper surface of the second wafer W2 in the radial direction (see FIG. 4).

Next, a grinding method of the wafer W (W1 and W2) according to embodiments of a first invention that is performed with use of the grinding apparatus 1 configured as described above will be explained.

### First Embodiment

First, the grinding method of the wafer W according to a first embodiment of the first invention will be described below with reference to FIGS. 2 through 5.

The grinding method of the wafer W (W1 and W2) according to the present embodiment is a method of grinding the wafer W (W1 and W2) through the following steps: 1) a first grinding step; 2) a thickness measuring step; 3) a nozzle positioning step; and 4) a second grinding step. In the following description, the first grinding step, the thickness measuring step, the nozzle positioning step, and the second grinding step will each be explained.

### 1) First Grinding Step:

The first grinding step is a step of grinding the first wafer W1 for testing (dummy). In this first grinding step, as illustrated in FIG. 2, the chuck table 10 is tilted by the unillustrated tilt adjusting mechanism such that the table rotational axis CL1 thereof is tilted by the illustrated angle α with respect to the vertical direction. Next, the first wafer W1 is placed on the holding surface 10a of the chuck table 10. Subsequently, the porous member 11 of the chuck table 10 is connected to an unillustrated suction source. As a result, the porous member 11 is vacuumed by the unillustrated suction source, so that a negative pressure is generated on the porous member 11, and the first wafer W1 attracted by this negative pressure is held under suction on the conical-shaped holding surface 10a of the chuck table 10. In this case, the thin first wafer W1 deforms to have an umbrella-like shape having the center as the vertex in line with the shape of the holding surface 10a of the chuck table 10.

Next, the chuck table 10 is horizontally moved in the +Y-axis direction (rightward in FIG. 2) together with the first wafer W1 held on the chuck table 10, by the horizontal movement mechanism 13, and the chuck table 10 is positioned such that a circumscribing circle of the annular ring-shaped grindstones 25b of the grinding wheel 25 passes through the center of the first wafer W1. Note that the tilt angle α of the chuck table 10 is set to such a value that the radial portion (right-half in FIG. 2) of the holding surface 10a of the chuck table 10 is parallel with the horizontal lower surface (grinding surface) of the grinding wheel 25.

In the abovementioned state, the chuck table 10 and the first wafer W1 held thereon are rotationally driven at a predetermined speed in an illustrated arrow direction (counterclockwise direction) about the table rotational axis as the table rotational axis CL1, by the table rotation mechanism 12, and the grinding wheel 25 is rotationally driven at a predetermined speed in the same direction (counterclockwise direction) as the rotation direction of the chuck table 10 about the grindstone rotational axis CL2, by the spindle motor 22 of the grinding unit 20 illustrated in FIG. 1. Then, from this state, when the grinding unit 20 is lowered by the lifting/lowering mechanism 30 and the grindstones 25b of the grinding wheel 25 come into contact with the radial portion on the upper surface of the first wafer W1, the entire surface of the first wafer W1 is ground (subjected to first grinding) by the grindstones 25b. Note that, at this time, grinding water flows from the grinding water supply source 41 of the grinding water supply mechanism 40 sequentially through a pipe 42 (see FIG. 1), the unillustrated supply channel formed along the axis of the spindle motor 22, the supply channel 23a formed along the axis of the spindle 23 illustrated in FIG. 2, and the plurality of supply channels 24a formed in the mount 24, and is jetted toward the upper surface of the first wafer W1 from the plurality of nozzles 25c formed vertically in the base 25a of the grinding wheel 25. Thus, grinding swarf generated by grinding of the first wafer W1 is removed by the grinding water, and the friction heat generated at the portion where the grindstones 25b and the first wafer W1 come into contact with each other is taken away by the grinding water, allowing the contact portion to be cooled.

Yet, even when the entire surface of the upper surface (reverse side) of the first wafer W1 is ground by the grindstones 25b in the first grinding step described above, due to the thermal deformation of the chuck table 10 alone caused by processing heat generated during the grinding processing, the first wafer W1 is unable to have a uniform thickness in the radial direction, and a thickness difference is unavoidably caused.

### 2) Thickness Measuring Step:

The thickness measuring step is a step of obtaining a thickness distribution of the first wafer W1 in the radial direction by measuring, at a plurality of locations in the radial direction, the thickness of the first wafer W1 which has been ground in the first grinding step. In this thickness measuring step, as illustrated in FIG. 3A, the grinding wheel 25 is lifted by the lifting/lowering mechanism 30, and the grindstones 25b are separated from the first wafer W1. Note that, at this time, the grinding wheel 25 is rotating, but may instead be stopped.

In the abovementioned state, when the support shaft 51 of the thickness measuring instrument 50 illustrated in FIG. 1 is rotated within a predetermined angle range by the motor 54, the arm 52 attached to the upper end of the support shaft 51 swings horizontally about the support shaft 51, so that the thickness sensor 53 attached to the distal end of the arm 52 moves toward the outer circumferential portion from the central portion on the upper side of the first wafer W1 as illustrated in FIG. 3A. In the present embodiment, the thickness of the first wafer W1 is optically measured by the thickness sensor 53 in a non-contact manner at five locations, i.e., a central portion A of the first wafer W1, an outer circumferential portion B thereof, an intermediate portion C between the central portion A and the outer circumferential portion B, a measurement portion D between the central portion A and the intermediate portion C, and a measurement portion E between the intermediate portion C and the outer circumferential portion B. That is, the thickness of the first wafer W1 is also measured at the two locations, i.e., the measurement portions D and E, in addition to the measurement locations (the central portion A, the intermediate portion C, and the outer circumferential portion B) used at the time of adjusting the tilting relation between the chuck table 10 and the grindstones 25b. Note that the measurement locations are not necessarily limited to the five locations mentioned above.

The results of measuring the thickness of the first wafer W1 at the central portion A, the measurement portion D, the intermediate portion C, the measurement portion E, and the outer circumferential portion B by the thickness sensor 53 as described above are indicated in FIG. 3B. In the present embodiment, a thickness t_{B} at the outer circumferential portion B of the first wafer W1 is the greatest.

Note that, in the present embodiment, as the thickness measuring instrument 50, a configuration in which the thickness sensor 53 is attached to the distal end of the arm 52 that horizontally swings about the support shaft 51 is used, but a configuration in which the thickness sensor is attached to five points in a horizontal arm that does not swing may instead be used.

### 3) Nozzle Positioning Step:

In the nozzle positioning step, the first wafer W1 held on the holding surface 10a of the chuck table 10 is removed, and the second wafer W2 as a product is held under suction on the holding surface 10a of the chuck table 10 as illustrated in FIG. 4. Subsequently, the jetting nozzle 60 is positioned directly above an outer circumferential portion of the second wafer W2 (outer circumferential portion of the second wafer W2 corresponding to the outer circumferential portion B having the great thickness t_{B} in the first wafer W1) that has a thickness t_{B} (>t₀) greater than a reference thickness t₀ which is set beforehand and illustrated in FIG. 3B. That is, when the motor 65 illustrated in FIG. 1 is activated and the support shaft 63 is rotated by a predetermined angle, the arm 64 attached to the upper end of the support shaft 63 horizontally swings, so that the jetting nozzle 60 attached to the distal end of the arm 64 moves horizontally on the upper side of the second wafer W2 and is positioned directly above the outer circumferential portion of the second wafer W2 as illustrated in FIG. 4.

### 4) Second Grinding Step:

In the second grinding step, as illustrated in FIG. 4, warm water is jetted from the jetting nozzle 60 positioned directly above the outer circumferential portion of the second wafer W2 (portion having a thickness greater than the reference thickness) in the nozzle positioning step toward the outer circumferential portion of the second wafer W2 from an outer side of the grindstones 25, and the outer circumferential portion is heated. That is, one on/off valve V1 illustrated in FIG. 1 is closed, and the other on/off valve V2 is opened, so that warm water from the warm water supply source 62 is supplied to the jetting nozzle 60, and the warm water is jetted from the jetting nozzle 60 toward the outer circumferential portion of the second wafer W2. Note that control is performed in such a manner that warm water is jetted from the jetting nozzle 60 when the thickness of the second wafer W2 becomes close to 1 μm short of the finishing thickness of 5 μm that is set beforehand.

Then, while warm water is being jetted from the jetting nozzle 60 toward the outer circumferential portion of the second wafer W2 as described above, as in the first grinding step, the upper surface (reverse side) of the second wafer W2 is ground (subjected to second grinding) by the rotating grindstones 25b of the grinding wheel 25, with the chuck table 10 and the second wafer W2 being rotated.

As described above, in the second grinding step, since the second wafer W2 is ground while warm water is being jetted from the jetting nozzle 60 to the outer circumferential portion of the second wafer W2 having a thickness that is one of the plurality of thicknesses measured in the thickness measuring step and that is greater than the reference thickness set beforehand, i.e., while the portion of the second wafer W2 having a thickness greater than the reference thickness is being heated and caused to swell by warm water, the grinding amount in the second grinding step of the outer circumferential portion of the second wafer W2 that has swelled by being heated (portion having a great thickness) becomes greater than those of other portions. Accordingly, when the temperature of the second wafer W2 returns to room temperature after the grinding processing, the thickness of the portion which had originally been greater than those of other portions becomes equivalent to those of other portions, so that the in-plane thickness difference is reduced, and the second wafer W2 is ground to a uniform thickness over the entire surface.

Incidentally, for the purpose of grinding the second wafer W2 to a more uniform thickness in the second grinding step, the tilt adjusting step described below may be performed after the thickness measuring step but before the second grinding step.

### 5) Tilt Adjusting Step:

The tilt adjusting step is a step of increasing the thickness of the outer circumferential portion (portion having a thickness greater than the reference thickness) of the first wafer W1 that has been ground in the first grinding step, by adjusting the tilt relation between the table rotational axis CL1 of the chuck table 10 and the grindstone rotational axis CL2 of the grinding wheel 25. Specifically, as illustrated in FIG. 5, a tilt angle β of the table rotational axis CL1 of the chuck table 10 is set to be greater than the tilt angle α illustrated in FIGS. 2 through 4 (β>α), by the unillustrated tilt adjusting mechanism.

As described above, in the tilt adjusting step, when the thickness of the outer circumferential portion of the first wafer W1 which has been ground in the first grinding step is made greater than the reference thickness and the thicknesses of portions other than the outer circumferential portion are made to have the reference thickness, since the outer circumferential portion of the second wafer W2 is ground after being heated and caused to swell by the warm water being jetted from the jetting nozzle 60 thereto in the next second grinding step, the grinding amount of the outer circumferential portion of the second wafer W2 having a great thickness can be increased, and the second wafer W2 can thus be ground to a much more uniform thickness over the entire surface in the second grinding step. Note that, in the present embodiment, since only the outer circumferential portion of the first wafer W1 ground in the first grinding step is made to have a thickness greater than the reference thickness by the tilt adjusting step as described above, the jetting nozzle 60 may be fixed in such a manner as to always jet warm water to the outer circumferential portion of the wafer W.

### Second Embodiment

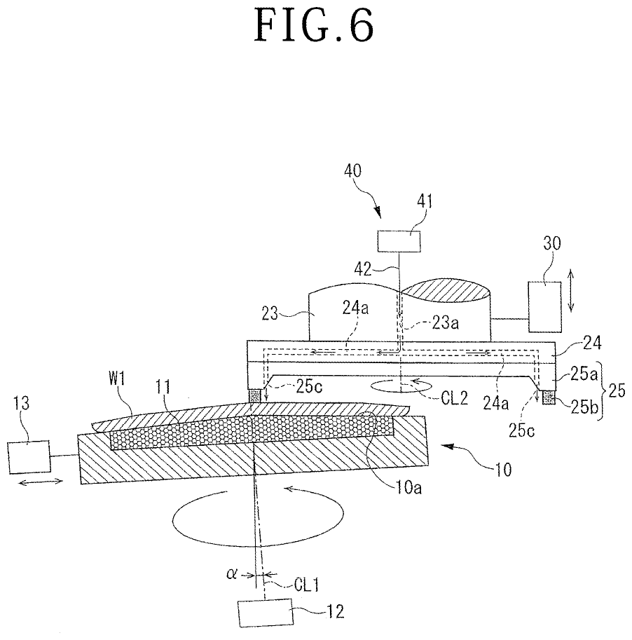

Next, a grinding method of the wafer W according to a second embodiment of the first invention will be described with reference to FIGS. 6 through 9.

The grinding method of the wafer W according to the present embodiment is also a method of grinding the wafer W through the following steps: 1) the first grinding step; 2) the thickness measuring step; 3) the nozzle positioning step; and 4) the second grinding step, similarly to the grinding method according to the first embodiment. In the following description, the first grinding step, the thickness measuring step, the nozzle positioning step, and the second grinding step will each be described.

### 1) First Grinding Step

The first grinding step is a step of grinding the first wafer W1 for testing (dummy), and is performed in a manner similar to that of the first grinding step according to the first embodiment, as illustrated in FIG. 6. Also in this first grinding step, due to the thermal deformation of the chuck table 10 alone caused by processing heat generated during grinding processing, the first wafer W1 is unable to have a uniform thickness in the radial direction, and a thickness difference is unavoidably caused in the radial direction.

### 2) Thickness Measuring Step:

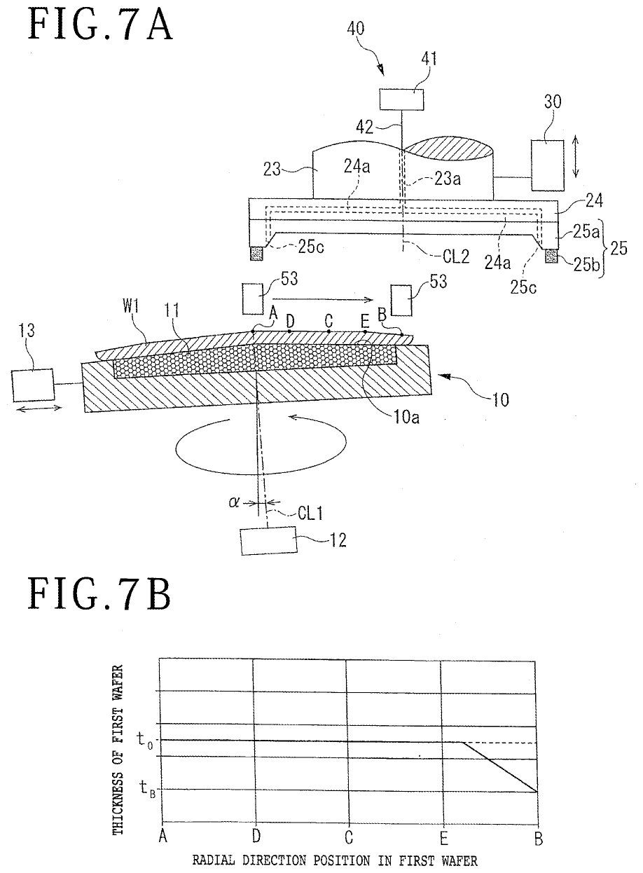

The thickness measuring step is a step of obtaining a thickness distribution of the first wafer W1 in the radial direction by measuring, at a plurality of locations in the radial direction, the thickness of the first wafer W1 which has been ground in the first grinding step. In this thickness measuring step, the grinding wheel 25 is lifted by the lifting/lowering mechanism 30, and the grindstones 25b are separated from the first wafer W1, as illustrated in FIG. 7A. Note that, at this time, the rotation of the grinding wheel 25 is stopped.

In the abovementioned state, when the support shaft 51 of the thickness measuring instrument 50 illustrated in FIG. 1 is rotated within a predetermined angle range by the motor 54, the arm 52 attached to the upper end of the support shaft 51 swings horizontally about the support shaft 51, so that the thickness sensor 53 attached to the distal end of the arm 52 moves toward the outer circumferential portion from the central portion on the upper side of the first wafer W1, as illustrated in FIG. 7A. Also in the present embodiment, the thickness of the first wafer W1 is optically measured by the thickness sensor 53 in a non-contact manner at five location, i.e., the central portion A, the measurement portion D, the intermediate portion C, the measurement portion E, and the outer circumferential portion B, of the first wafer W1, as in the first embodiment.

The results of measurement of the thickness of the first wafer W1 at the central portion A, the measurement portion D, the intermediate portion C, the measurement portion E, and the outer circumferential portion B by the thickness sensor 53 as described above are indicated in FIG. 7B. In the present embodiment, the thickness t_{B} at the outer circumferential portion B of the first wafer W1 is the smallest.

### 3) Nozzle Positioning Step:

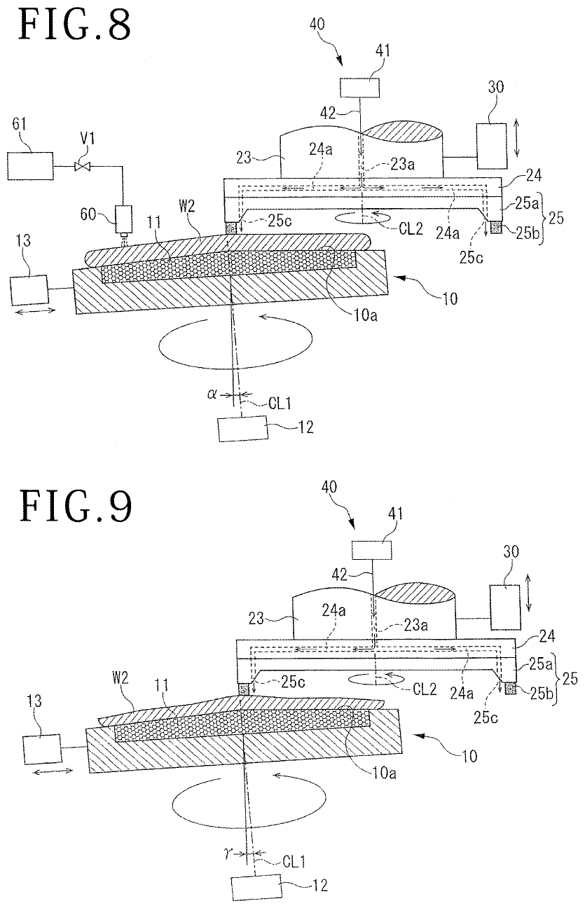

In the nozzle positioning step, the first wafer W1 held on the holding surface 10a of the chuck table 10 is removed, and the second wafer W2 as a product is held under suction on the holding surface 10a of the chuck table 10 as illustrated in FIG. 8. Subsequently, as in the first embodiment, the jetting nozzle 60 is positioned directly above the outer circumferential portion B of the second wafer W2 that has a thickness t_{B} (<t₀) smaller than the reference thickness t₀ which is set beforehand and illustrated in FIG. 7B.

### 4) Second Grinding Step

In the second grinding step, as illustrated in FIG. 8, cold water is jetted toward the outer circumferential portion (portion having a thickness smaller than the reference thickness) of the second wafer W2 from the jetting nozzle 60 positioned directly above the outer circumferential portion of the second wafer W2 in the nozzle positioning step, and the outer circumferential portion is cooled. Specifically, one on/off valve V2 illustrated in FIG. 1 is closed, while the other on/off valve V1 is opened, so that cold water from the cold water supply source 61 is supplied to the jetting nozzle 60, and the cold water is jetted from the jetting nozzle 60 toward the outer circumferential portion of the second wafer W2.

Then, while cold water is being jetted toward the outer circumferential portion of the second wafer W2 from the jetting nozzle 60 as described above, the upper surface (reverse side) of the second wafer W2 is ground (subjected to second grinding) by the rotating grindstones 25b of the grinding wheel 25, with the chuck table 10 and the second wafer W2 being rotated, as in the first grinding step.

As described above, in the second grinding step, since the second wafer W2 is ground while cold water is being jetted from the jetting nozzle 60 to the outer circumferential portion of the second wafer W2 which has a thickness that is one of the plurality of thicknesses measured in the thickness measuring step and that is smaller than the reference thickness set beforehand, i.e., while the portion of the second wafer W2 having a thickness smaller than the reference thickness is being cooled and caused to contract by cold water, the grinding amount in the second grinding step of the portion of the second wafer W2 that has contracted by being cooled (portion having a small thickness) becomes smaller than those of other portions. Accordingly, when the temperature of the second wafer W2 returns to room temperature after the grinding processing, the thickness of the portion that had originally been smaller than the thicknesses of other portions becomes equivalent to those of other portions, so that the in-plane thickness difference is reduced, and the second wafer W2 can be ground to a uniform thickness over the entire surface.

Incidentally, for the purpose of allowing the second wafer W2 to be ground to a more uniform thickness in the second grinding step, the tilt adjusting step described below may be performed after the thickness measuring step but before the second grinding step.

### 5) Tilt Adjusting Step:

The tilt adjusting step is a step of reducing the thickness of the outer circumferential portion of the first wafer W1 ground in the first grinding step, by adjusting the tilt relation between the table rotational axis CL1 of the chuck table 10 and the grindstone rotational axis CL2 of the grinding wheel 25. Specifically, as illustrated in FIG. 9, a tilt angle γ of the table rotational axis CL1 of the chuck table 10 is set to be smaller than the tilt angle α illustrated in FIG. 8, by the unillustrated tilt adjusting mechanism (γ<α). Further, the tilt is changed also in the direction orthogonal to the sheet direction of FIG. 8.

When the thickness of the outer circumferential portion of the first wafer W1 ground in the first grinding step is reduced in the tilt adjusting step, as described above, the grinding amount of the outer circumferential portion of the second wafer W2 can be reduced by cold water being jetted from the jetting nozzle 60 to the outer circumferential portion of the second wafer W2 and the outer circumferential portion being cooled, in the next second grinding step, so that the second wafer W2 can be ground to a more uniform thickness over the entire surface in the second grinding step.

Note that the position to which warm water or cold water is to be jetted is not limited to the outer circumferential portion. For example, in a case where the measurement portion E has a great thickness, the jetting nozzle 60 may be positioned directly above the measurement portion E, and the measurement portion E may be ground to a predetermined thickness while warm water is being jetted thereto, thus allowing the second wafer W2 to be ground to a uniform thickness.

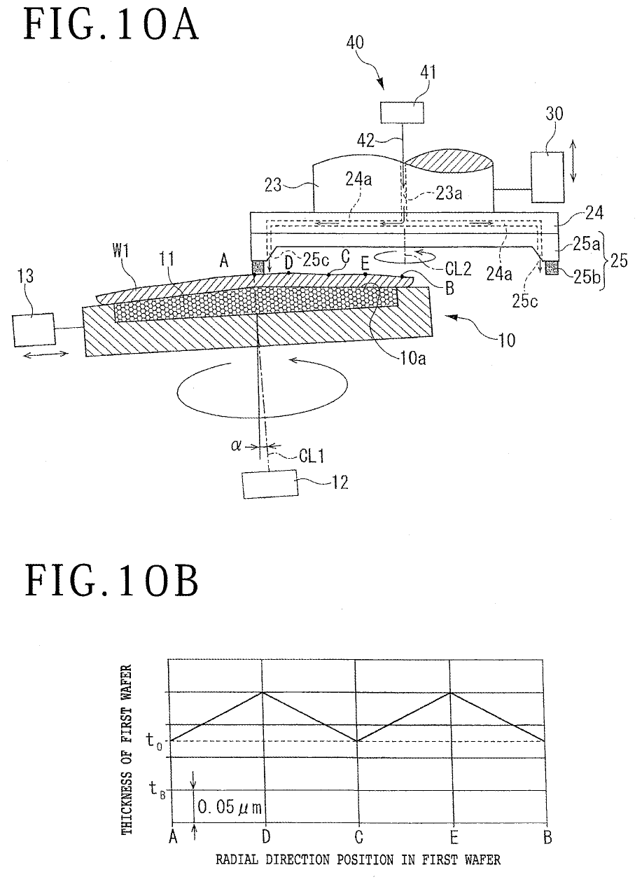

Moreover, the number of locations to which warm water or cold water is to be jetted is not limited to one. A configuration in which warm water or cold water is jetted to two locations in the radial portion of the second wafer W2 may be adopted. For example, as illustrated in FIGS. 10A and 10B, in a case where the measurement portions D and E have great thicknesses, the jetting nozzle 60 is positioned directly above each of the measurement portion D and the measurement portion E. Subsequently, the second wafer W2 is ground to a predetermined thickness while warm water is being jetted from two jetting nozzles 60, so that the second wafer W2 can be ground to a uniform thickness. Note that the jetting nozzle 60 may have such a configuration including a cold water jetting nozzle for jetting cold water and a warm water jetting nozzle for jetting warm water.

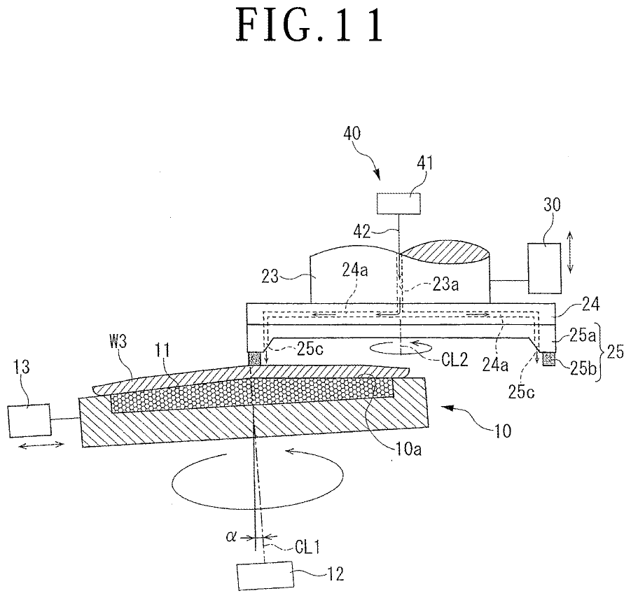

Next, a grinding method of the wafer W according to a second invention will be described with reference to FIGS. 11 through 13.

The grinding method of the wafer W according to the second invention is also similar to the grinding method according to the first invention and is a method of grinding the wafer W to a finishing thickness through the following steps: 1) the first grinding step; 2) the thickness measuring step; 3) the nozzle positioning step; and 4) the second grinding step. In the following description, the first grinding step, the thickness measuring step, the nozzle positioning step, and the second grinding step will each be explained.

### 1) First Grinding Step:

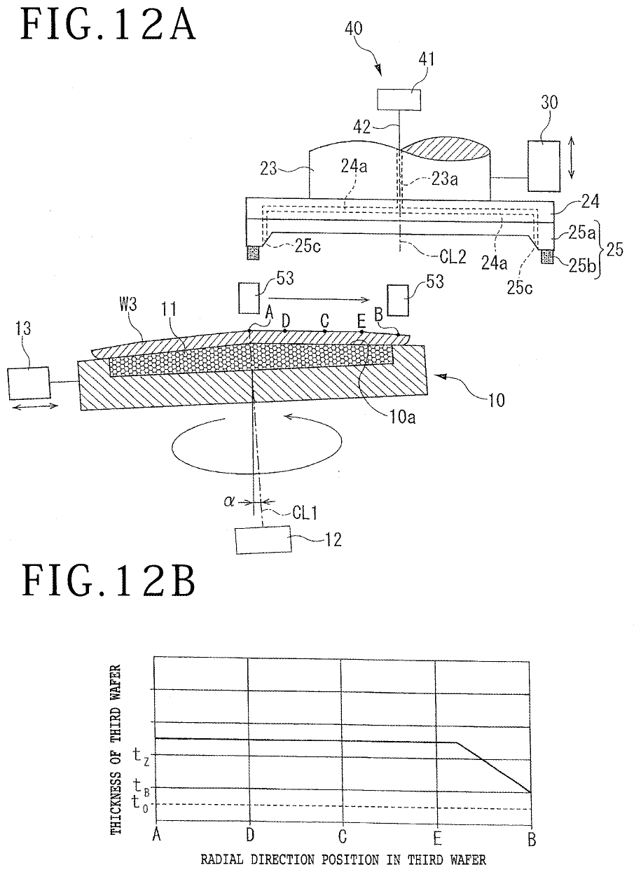

The first grinding step is, as illustrated in FIG. 11, a step of grinding a wafer W3 as a product to a thickness t_{z} that is short of the finishing thickness set beforehand. Also in this first grinding step, due to the thermal deformation of the chuck table 10 alone caused by processing heat generated during the grinding processing, the wafer W3 is unable to have a uniform thickness in the radial direction, and a thickness difference is unavoidably caused in the radial direction. Note that the thickness t_{z} short of the finishing thickness is set in the grinding condition of the grinding apparatus (see FIG. 12B).

### 2) Thickness Measuring Step:

The thickness measuring step is, as illustrated in FIGS. 12A and 12B, a step of obtaining a thickness distribution of the wafer W3 in the radial direction by measuring, at a plurality of locations (five portions A through E in the present embodiment) in the radial direction, the thickness of the wafer W3 which has been ground in the first grinding step. In this thickness measuring step, the thickness of each of the five portions A through E is measured by lifting the grinding wheel 25 by the lifting/lowering mechanism 30, causing the grindstones 25b to separate from the wafer W3, and moving the thickness sensor 53 of the thickness measuring instrument 50 in a direction parallel to an upper surface of the wafer W3 between the wafer W3 and the lower surfaces of the grindstones 25b. Note that, at this time, the rotation of the grinding wheel 25 may either be stopped or maintained. Here, the thicknesses measured at the five portions are each greater than the finishing thickness set beforehand.

In the abovementioned state, when the support shaft 51 of the thickness measuring instrument 50 illustrated in FIG. 1 is rotated within a predetermined angle range by the motor 54, the arm 52 attached to the upper end of the support shaft 51 swings horizontally about the support shaft 51, so that the thickness sensor 53 attached to the distal end of the arm 52 moves toward the outer circumferential portion from the central portion on the upper side of the wafer W3 as illustrated in FIG. 12A. Also in the present embodiment, as in the first invention, the thickness of the wafer W3 is optically measured by the thickness sensor 53 in a non-contact manner at five locations, i.e., the central portion A, the measurement portion D, the intermediate portion C, the measurement portion E, and the outer circumferential portion B of the wafer W3. Note that the thickness sensor 53 may be a height gauge that measures the height of the upper surface of the wafer W3 in a contact manner. In that case, the thickness sensor 53 includes a calculation section that obtains a difference between the height of the upper surface of the wafer W3 and the height of the holding surface holding the wafer W3, and the difference calculated by the calculation section may be used as the thickness of the wafer W3.

The results of measuring the thickness of the wafer W3 at the central portion A, the measurement portion D, the intermediate portion C, the measurement portion E, and the outer circumferential portion B as described above are indicated in FIG. 12B. In the present embodiment, the thickness t_{B} at the outer circumferential portion B of the wafer W3 is the smallest.

### 3) Nozzle Positioning Step:

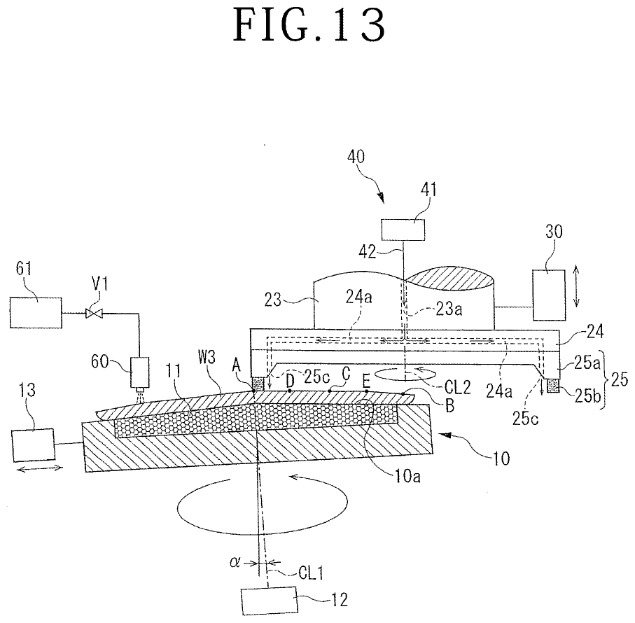

As illustrated in FIG. 13, the jetting nozzle 60 is positioned directly above the outer circumferential portion B of the wafer W3 that is held on the holding surface 10a of the chuck table 10 and that has been ground to the thickness t_{z} short of the finishing thickness t₀ and is yet to be ground to the finishing thickness t₀, as in the first invention. Note that the outer circumferential portion B of the wafer W3 has the thickness t_{B} (<t_{z}) that is smaller than the thickness t_{z} short of the finishing thickness t₀ which is set beforehand and illustrated in FIG. 12B.

### 4) Second Grinding Step:

In the second grinding step, as illustrated in FIG. 13, cold water is jetted toward the outer circumferential portion of the wafer W3 (portion having a thickness smaller than the thickness t_{z} short of the finishing thickness t₀) from the jetting nozzle 60 positioned directly above the outer circumferential portion of the wafer W3 in the nozzle positioning step, and the outer circumferential portion is cooled. Specifically, one on/off valve V2 illustrated in FIG. 1 is closed, and the other on/off valve V1 is opened, so that cold water from the cold water supply source 61 is supplied to the jetting nozzle 60, and the cold water is jetted from the jetting nozzle 60 toward the outer circumferential portion of the wafer W3.

Next, as described above, while cold water is being jetted toward the outer circumferential portion of the wafer W3 from the jetting nozzle 60, the upper surface (reverse side) of the wafer W3 is ground (subjected to second grinding) by the rotating grindstones 25b of the grinding wheel 25, with the chuck table 10 and the wafer W3 being rotated, as in the first grinding step.

As described above, in the second grinding step, since the wafer W3 is ground while cold water is being jetted from the jetting nozzle 60 to the outer circumferential portion of the wafer W3 having the thickness t_{B} that is one of the plurality of thicknesses measured in the thickness measuring step and that is smaller than the thickness t_{z} short of the finishing thickness t₀ set beforehand, i.e., while the portion of the wafer W3 having a thickness smaller than the thickness t_{z} short of the finishing thickness t₀ is being cooled and caused to contract by cold water, the grinding amount in the second grinding step of the portion of the wafer W3 that has contracted by being cooled (portion having a small thickness) becomes smaller than those of other portions. Accordingly, when the temperature of the wafer W3 returns to room temperature after the grinding processing, the thickness of the portion which had originally been smaller than those of other portions becomes equivalent to those of the other portions, so that the in-plane thickness difference is reduced, and the wafer W3 can be ground to a uniform thickness over the entire surface.

Note that the abovementioned embodiments have been described by taking, as an example, cases where focus is placed only on the outer circumferential portion of the wafer W (W1, W2, and W3) and where the thickness of the outer circumferential portion is either greater or smaller than the reference thickness. Yet, it should be noted that, also in the cases where the central portion or the intermediate portion of the wafer W is either greater or smaller than the reference thickness, the advantageous effects described above can be obtained by the second grinding being performed while warm water or cold water is being jetted toward the central portion or the intermediate portion having a thickness greater than the reference thickness in the second grinding step.

In addition, the present invention is by no means limited to being applied to the embodiments described above, and various modifications can obviously be made within the scope of the technical ideas described in the claims, the specification, and the drawings.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer grinding apparatus for grinding a wafer by a lower surface of an annular grindstone that is caused to come into contact with a radial portion of the wafer, the wafer grinding apparatus comprising:
a chuck table for holding the wafer by a conical-shaped holding surface having a center as a vertex;
a table rotation mechanism for rotating the chuck table about a table rotational axis passing through the vertex, as an axis;
a grinding unit for rotating the grindstone about a grindstone rotational axis passing through a center of the grindstone, as an axis, and grinding the wafer;
a lifting/lowering mechanism for lifting and lowering the grinding unit in a direction approaching and separating from the holding surface;
a thickness measuring instrument for measuring a thickness of the wafer ground by the grinding unit;
a grinding water supply mechanism for supplying grinding water to an inner side of the grindstone; and
a jetting nozzle for jetting cold water or warm water to at least a portion on an upper surface of the wafer at an outer side of the grindstone that is performing grinding processing, wherein
the wafer is ground in such a state where at least a portion of the wafer is caused to contract or swell in a ring shape by a rotation operation of the chuck table by the table rotation mechanism and the cold water or the warm water jetted from the jetting nozzle, in order to allow the wafer that has returned to room temperature after being ground to have a uniform thickness.

2. A wafer grinding method performed with use of a grinding apparatus that grinds a wafer by a lower surface of a grindstone that is caused to come into contact with a radial portion of the wafer,
the grinding apparatus including
a chuck table for holding the wafer by a conical-shaped holding surface having a center as a vertex,
a table rotation mechanism for rotating the chuck table about a table rotational axis passing through the vertex, as an axis,
a grinding unit for rotating the grindstone about a grindstone rotational axis passing through a center of the grindstone, as an axis, and grinding the wafer,
a lifting/lowering mechanism for lifting and lowering the grinding unit in a direction approaching and separating from the holding surface,
a thickness measuring instrument for measuring a thickness of the wafer ground by the grinding unit,
a grinding water supply mechanism for supplying grinding water to an inner side of the grindstone, and
a jetting nozzle for jetting cold water or warm water to at least a portion on an upper surface of the wafer at an outer side of the grindstone that is performing grinding processing,
the wafer grinding method comprising:
a first grinding step of grinding a first wafer held on the chuck table to a finishing thickness;
a thickness measuring step of measuring, at a plurality of locations in a radial direction, a thickness of the first wafer ground in the first grinding step;
a nozzle positioning step of positioning the jetting nozzle directly above a portion of the first wafer having a thickness that is one of the thicknesses of the first wafer measured at the plurality of locations in the thickness measuring step and that is either greater or smaller than a reference thickness set beforehand; and
a second grinding step of grinding a second wafer next held on the chuck table, by jetting warm water to the second wafer from the jetting nozzle positioned directly above a portion of the second wafer having a thickness greater than the reference thickness in the nozzle positioning step or jetting cold water to the second wafer from the jetting nozzle positioned directly above a portion of the second wafer having a thickness smaller than the reference thickness in the nozzle positioning step.

3. The wafer grinding method according to claim 2, further comprising:
a tilt adjusting step of, after the thickness measuring step but before the second grinding step, adjusting a tilt relation between the table rotational axis and the grindstone rotational axis, either increasing or reducing the thickness of an outer circumferential portion of the first wafer ground in the first grinding step, and causing portions other than the outer circumferential portion to have a reference thickness.

4. A wafer grinding method performed with use of a grinding apparatus that grinds a wafer by a lower surface of a grindstone that is caused to come into contact with a radial portion of the wafer,
the grinding apparatus including
a chuck table for holding the wafer by a conical-shaped holding surface having a center as a vertex,
a table rotation mechanism for rotating the chuck table about a table rotational axis passing through the vertex, as an axis,
a grinding unit for rotating the grindstone about a grindstone rotational axis passing through a center of the plurality of grindstones that are disposed in an annular shape, as an axis, and grinding the wafer,
a lifting/lowering mechanism for lifting and lowering the grinding unit in a direction approaching and separating from the holding surface,
a thickness measuring instrument for measuring a thickness of the wafer ground by the grinding unit,
a grinding water supply mechanism for supplying grinding water to an inner side of the grindstone, and
a jetting nozzle for jetting cold water or warm water to at least a portion on an upper surface of the wafer at an outer side of the grindstone that is performing grinding processing,
the wafer grinding method comprising:
a first grinding step of grinding the wafer held on the chuck table to a thickness short of a finishing thickness;
a thickness measuring step of measuring, at a plurality of locations in a radial direction, the thickness of the wafer ground in the first grinding step;
a nozzle positioning step of positioning the jetting nozzle directly above a portion of the wafer having a thickness that is one of the thicknesses of the wafer measured at the plurality of locations in the thickness measuring step and that is either greater or smaller than a reference thickness set beforehand; and
a second grinding step of grinding the wafer to the finishing thickness by jetting warm water to the wafer from the jetting nozzle positioned directly above the portion of the wafer having a thickness greater than the reference thickness in the nozzle positioning step or jetting cold water to the wafer from the jetting nozzle positioned directly above the portion of the wafer having a thickness smaller than the reference thickness in the nozzle positioning step.
